(19) United States
(12) Patent Application Publication
(10) Pub. No.: US 2022/0100090 A1
(43) Pub. Date: Mar. 31, 2022

(54) COLORED PHOTOSENSITIVE RESIN COMPOSITION AND BLACK MATRIX PREPARED THEREFROM

(71) Applicant: ROHM AND HAAS ELECTRONIC MATERIALS KOREA LTD., Chungcheongnam-do (KR)

(72) Inventors: Seung-Keun KIM, Gyeonggi-do (KR); Kyu cheol LEE, Gyeonggi-do (KR)

(21) Appl. No.: 17/548,709

(22) Filed: Dec. 13, 2021

Related U.S. Application Data
(63) Continuation of application No. 16/710,554, filed on Dec. 11, 2019, now abandoned.

(30) Foreign Application Priority Data
Dec. 21, 2018 (KR) 10-2018-0166998
Dec. 4, 2019 (KR) 10-2019-0159790

(51) Int. Cl. G03F 7/031; G03F 7/033

(52) U.S. Cl. CPC G03F 7/031; G03F 7/033

(57) ABSTRACT

The present invention relates to a colored photosensitive resin composition and to a light-shielding black matrix prepared therefrom. The colored photosensitive resin composition of the present invention is capable of providing a cured film that satisfies such characteristics as high light-shielding property and low reflectance at the same time by more effectively reducing the total reflectance, which is a smaller-the-better characteristic that should be satisfied as a light-shielding black matrix, while the optical density, resolution, leveling characteristics, visibility, and the like are maintained to be excellent. Thus, the light-shielding black matrix prepared from the composition can be advantageously used in liquid crystal displays and quantum dot displays.

### CLAIM OF BENEFIT OF PRIOR APPLICATION

This application claims priority under 35 U.S.C. §120 from U.S. patent application Ser. No. 16/710,554, filed Dec. 11, 2019, which is the U.S. Entry of KR 10-2018-0166998, filed Dec. 21, 2018 and KR10-2019-0159790, filed Dec. 4, 2019, all of which are incorporated by reference herein in their entirety.

### TECHNICAL FIELD

The present invention relates to a colored photosensitive resin composition that satisfies such characteristics as high light-shielding property and low reflectance upon forming a cured film and a black matrix prepared from the same and used in liquid crystal displays and quantum dot displays.

### BACKGROUND ART OF THE INVENTION

In liquid crystal displays (LCDs) and quantum dot (QD)-based displays that have been recently developed and use an LED backlight, reflective polarizing films, color filters, and the like are employed.

A color filter is generally in the form of a thin film that allows color to be realized. It is prepared by forming color patterns of sequential type, sprite type, or mosaic type in different colors of red, green, and blue on the surface of a transparent substrate such as glass and a plastic sheet on which a black matrix is formed. In such event, the black matrix used as a light-shielding film serves to prevent a deterioration in contrast and color purity caused by light leakage between pixels.

A black matrix is generally prepared by mixing a photosensitive binder with a pigment. However, since the content of the pigment in the binder is low, there is a disadvantage in that the light-shielding property per unit film thickness is very low. In addition, a black matrix has a disadvantage in terms of chromaticity and brightness since a reflected image is viewed from the front.

In the related art, various techniques to address the above problems have been proposed (see, e.g., Japanese Patent No. 6318699). But studies have continued to further improve the total reflectance, which is a smaller-the-better characteristic (i.e., a characteristic in which the resulting data value is expected to be smaller), and the light-shielding property that should be satisfied as a black matrix.

### PRIOR ART DOCUMENT

### Patent Document

(Patent Document 1) Japanese Patent No. 6318699

### DISCLOSURE OF THE INVENTION

### Problem to be Solved

Accordingly, an object of the present invention is to provide a colored photosensitive resin composition capable of forming a cured film whose characteristics in terms of high light-shielding property and low reflectance are further enhanced and a black matrix prepared from the same.

### Solution to the Problem

In order to achieve the above object, the present invention provides a photosensitive resin composition, which comprises (A) a copolymer, (B) a photopolymerizable compound, (C) a photopolymerization initiator, and (D) a colorant, wherein the colorant (D) comprises at least one colorant selected from the group consisting of a black organic colorant, a black inorganic colorant, and a colorant other than black, and when a cured film having a thickness of 3 μm formed from the photosensitive resin composition is measured by the SCI method at a wavelength of 360 to 740 nm, it shows a total reflectance of 4.6% or less.

In order to achieve another object, the present invention provides a cured film prepared from the photosensitive resin composition.

### Advantageous Effects of the Invention

The colored photosensitive resin composition of the present invention is capable of providing a cured film that satisfies such characteristics as high light-shielding property and low reflectance at the same time by more effectively reducing the total reflectance, which is a smaller-the-better characteristic that should be satisfied as a light-shielding black matrix, while the optical density, resolution, leveling characteristics, visibility, and the like are maintained to be excellent. Thus, the light-shielding black matrix prepared from the composition can be advantageously used in liquid crystal displays and quantum dot displays.

### BRIEF DESCRIPTION OF THE DRAWINGS

FIG. 1 is a graph showing the total reflectance, scattered reflectance, and specular reflectance of the cured films prepared from the compositions of Examples 1 to 9 and Comparative Examples 1 to 5.

FIGS. 2 and 3 are photographs of the surface of the cured films prepared from the compositions of the Examples 1 to 9 and Comparative Examples 1 to 5 taken with an optical microscope.

FIG. 4 is a graph showing the total reflectance, scattered reflectance, and specular reflectance of the cured films prepared from the compositions of Examples 10 to 17 and Comparative Examples 6 to 8.

FIGS. 5 and 6 are photographs of the surface of the cured films prepared from the compositions of the Examples 10 to 17 and Comparative Examples 6 to 8 taken with an optical microscope.

FIG. 7 is a photograph of the cross-section of the cured films prepared from the compositions of Examples 1, 2, 10, and 11 taken with a scanning electron microscope (SEM).

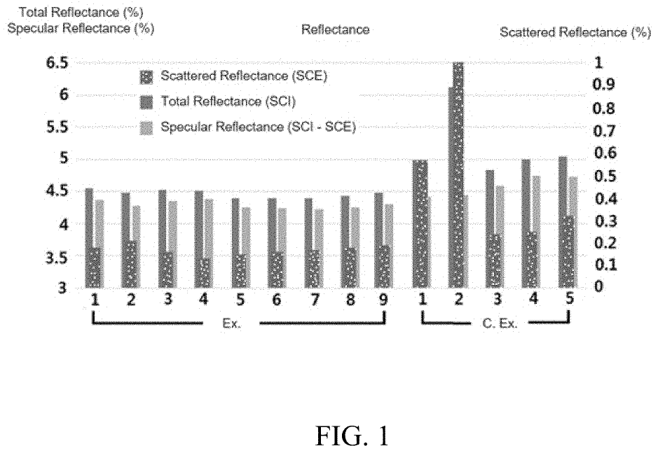

### DETAILED DESCRIPTION FOR CARRYING OUT THE INVENTION

The present invention is not limited to those described below. Rather, it can be modified into various forms as long as the gist of the invention is not altered.

Throughout the present specification, when a part is referred to as “comprising” an element, it is understood that other elements may be comprised, rather than other elements are excluded, unless specifically stated otherwise. In addition, all numbers and expressions relating to quantities of components, reaction conditions, and the like used herein are to be understood as being modified by the term “about” unless specifically stated otherwise.

The present invention provides a photosensitive resin composition, which comprises (A) a copolymer, (B) a photopolymerizable compound, (C) a photopolymerization initiator, and (D) a colorant, wherein the colorant (D) comprises at least one colorant selected from the group consisting of a black organic colorant, a black inorganic colorant, and a colorant other than black.

The composition may optionally further comprise (E) a surfactant, (F) a copolymer different from the copolymer (A), and/or (G) a solvent.

In such event, when a cured film having a thickness of 3μm formed from the photosensitive resin composition is measured by the SCI method at a wavelength of 360 to 740 nm, it shows a total reflectance of 4.6% or less. The total reflectance may be expressed as a specular component included (SCI) and refers to total reflectance including specular reflection and scattered reflection.

Hereinafter, each component of the photosensitive resin composition will be explained in detail.

As used herein, the term “(meth)acryl” refers to “acryl” and/or “methacryl,” and the term “(meth)acrylate” refers to “acrylate” and/or “methacrylate.”

The weight average molecular weight (g/mole, Da) of each component as described below is measured by gel permeation chromatography (GPC, eluent: tetrahydrofuran) referenced to a polystyrene standard.

(A) Copolymer

The copolymer (A) employed in the present invention may comprise (a-1) a structural unit derived from an ethylenically unsaturated carboxylic acid, an ethylenically unsaturated carboxylic anhydride, or a combination thereof, (a-2) a structural unit derived from an ethylenically unsaturated compound containing an aromatic ring, (a-3) a structural unit derived from an ethylenically unsaturated compound containing an epoxy group, and optionally (a-4) a structural unit derived from an ethylenically unsaturated compound different from (a-1), (a-2), and (a-3).

The copolymer (A) is an alkali-soluble resin for developability and also plays the role of a base for forming a film upon coating and a structure for forming a final pattern.

(a-1) Structural unit derived from an ethylenically unsaturated carboxylic acid, an ethylenically unsaturated carboxylic anhydride, or a combination thereof

The structural unit (a-1) is derived from an ethylenically unsaturated carboxylic acid, an ethylenically unsaturated carboxylic anhydride, or a combination thereof The ethylenically unsaturated carboxylic acid and the ethylenically unsaturated carboxylic anhydride is a polymerizable unsaturated monomer containing at least one carboxyl group in the molecule. Particular examples thereof may include an unsaturated monocarboxylic acid such as (meth)acrylic acid, crotonic acid, α-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; an unsaturated polycarboxylic acid of trivalence or more and an anhydride thereof; and a mono[(meth)acryloyloxyalkyl] ester of a polycarboxylic acid of divalence or more such as mono [2-(meth)acryloyloxyethyl] succinate, mono[2-(meth)acryloyloxyethyl] phthalate, and the like. The structural unit derived from the above-exemplified compounds may be comprised in the copolymer alone or in combination of two or more.

The amount of the structural unit (a-1) may be 5 to 65% by mole, 10 to 50% by mole, 10 to 40% by mole, 15 to 40% by mole, 20 to 40% by mole, or 25 to 40% by mole, based on the total moles of the structural units constituting the copolymer (A). Within the above range, it may have favorable developability.

(a-2) Structural unit derived from an ethylenically unsaturated compound containing an aromatic ring

The structural unit (a-2) is derived from an ethylenically unsaturated compound containing an aromatic ring. Particular examples of the ethylenically unsaturated compound containing an aromatic ring may include phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tribromophenyl (meth)acrylate; styrene; styrene containing an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; styrene containing a halogen such as fluorostyrene, chlorostyrene, bromostyrene, and iodostyrene; styrene containing an alkoxy substituent such as methoxystyrene, ethoxystyrene, and propoxystyrene; 4-hydroxystyrene, p-hydroxy-a-methylstyrene, acetylstyrene; and vinyltoluene, divinylbenzene, vinylphenol, o-vinylbenzyl methyl ether, m-vinylbenzyl methyl ether, p-vinylbenzyl methyl ether, o-vinylbenzyl glycidyl ether, m-vinylbenzyl glycidyl ether, p-vinylbenzyl glycidyl ether, and the like. The structural unit derived from the above-exemplified compounds may be comprised in the copolymer alone or in combination of two or more. For polymerizability of the composition, a structural unit derived from styrene compounds is preferred among these examples.

The amount of the structural unit (a-2) may be 1 to 50% by mole, 3 to 40% by mole, 3 to 30% by mole, 3 to 20% by mole, or 3 to 10% by mole, based on the total moles of the structural units constituting the copolymer (A). Within the above content range, it may be more advantageous in terms of chemical resistance.

(a-3) Structural unit derived from an ethylenically unsaturated compound containing an epoxy group

The structural unit (a-3) is derived from an ethylenically unsaturated compound containing an epoxy group. Particular examples of the ethylenically unsaturated compound containing an epoxy group may include glycidyl (meth)acrylate, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, 4-hydroxybutyl (meth)acrylate glycidyl ether, allyl glycidyl ether, 2-methylallyl glycidyl ether, and the like. The structural unit derived from the above-exemplified compounds may be comprised in the copolymer alone or in combination of two or more. A structural unit derived from glycidyl (meth)acrylate and/or 4-hydroxybutyl (meth)acrylate glycidyl ether among the above is more preferable from the viewpoint of copolymerizability and enhancements in the strength of a cured film.

The amount of the structural unit (a-3) may be 1 to 40% by mole, 5 to 30% by mole, 5 to 20% by mole, 7 to 15% by mole, or 5 to 15% by mole, based on the total moles of the structural units constituting the copolymer (A). Within the above range, it may be more advantageous in terms of residues during the process and margins upon pre-bake.

(a-4) Structural unit derived from an ethylenically unsaturated compound different from (a-1), (a-2), and (a-3)

The copolymer (A) employed in the present invention may further comprise a structural unit derived from an ethylenically unsaturated compound different from (a-1), (a-2), and (a-3) in addition to (a-1), (a-2), and (a-3).

Particular examples of the structural unit derived from an ethylenically unsaturated compound different from the structural units (a-1), (a-2), and (a-3) may include an unsaturated carboxylic acid ester such as methyl (meth)acrylate, ethyl (meth)acrylate, butyl (meth)acrylate, dimethylaminoethyl (meth)acrylate, isobutyl (meth)acrylate, n-butyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl a-hydroxymethylacrylate, ethyl a-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; a tertiary amine containing an N-vinyl group such as N-vinyl pyrrolidone, N-vinyl carbazole, and N-vinyl morpholine; an unsaturated ether such as vinyl methyl ether and vinyl ethyl ether; an unsaturated imide such as N-phenylmaleimide, N-(4-chlorophenyl)maleimide, N-(4-hydroxyphenyl)maleimide, N-cyclohexylmaleimide, and the like. The structural unit derived from the above-exemplified compounds may be comprised in the copolymer alone or in combination of two or more. A structural unit derived from an unsaturated imide, specifically N-substituted maleimide, among the above is more preferable from the viewpoint of copolymerizability and enhancements in the strength of a cured film.

The amount of the structural unit (a-4) may be greater than 0 to 80% by mole, 30 to 70% by mole, 30 to 60% by mole, 40 to 70% by mole, or 40 to 60% by mole, based on the total moles of the structural units constituting the copolymer (A). Within the above range, the storage stability of the colored photosensitive resin composition may be maintained, and the film retention rate may be more advantageously enhanced.

Examples of the copolymer having the structural units (a-1) to (a-4) may include a copolymer of (meth)acrylic acid/styrene/methyl (meth)acrylate/glycidyl (meth)acrylate, a copolymer of (meth)acrylic acid/styrene/methyl (meth)acrylate/glycidyl (meth)acrylate/N-phenylmaleimide, a copolymer of (meth)acrylic acid/styrene/methyl (meth)acrylate/glycidyl (meth)acrylate/N-cyclohexylmaleimide, a copolymer of (meth)acrylic acid/styrene/n-butyl (meth)acrylate/glycidyl (meth)acrylate/N-phenylmaleimide, a copolymer of (meth)acrylic acid/styrene/glycidyl (meth)acrylate/N-phenylmaleimide, a copolymer of (meth)acrylic acid/styrene/4-hydroxybutyl (meth)acrylate glycidyl ether/N-phenylmaleimide, and the like. One, two, or more of the copolymers may be comprised in the colored photosensitive resin composition.

The weight average molecular weight of the copolymer (A) may be 5,000 to 30,000 Da or 7,000 to 20,000 Da. If the weight average molecular weight of the copolymer (A) is within the above range, the step difference by a lower pattern may be advantageously improved, and a pattern profile upon development may be favorable.

The amount of the copolymer (A) in the colored photosensitive resin composition may be 5 to 40% by weight, 5 to 35% by weight, 10 to 35% by weight or 10 to 30% by weight, based on the total weight of the solids content (i.e., the weight excluding solvents) of the colored photosensitive resin composition. Within the above range, a pattern profile upon development may be favorable, and such properties as film retention rate and chemical resistance may be enhanced.

The copolymer (A) may be prepared by charging to a reactor a radical polymerization initiator, a solvent, and the structural units (a-1) to (a-4), followed by charging nitrogen thereto and slowly stirring the mixture for polymerization.

The radical polymerization initiator may be an azo compound such as 2,2′-azobisisobutyronitrile, 2,2′-azobis(2,4-dimethylvaleronitrile), and 2,2′-azobis(4-methoxy-2,4-dimethylvaleronitrile); or benzoyl peroxide, lauryl peroxide, t-butyl peroxypivalate, 1,1-bis(t-butylperoxy)cyclohexane, or the like, but it is not limited thereto. The radical polymerization initiator may be used alone or in combination of two or more.

The solvent may be any conventional solvent commonly used in the preparation of the copolymer (A) and may include, for example, propylene glycol monomethyl ether acetate (PGMEA).

(B) Photopolymerizable compound

The photopolymerizable compound (B) employed in the present invention may be a monofunctional or polyfunctional ester compound having at least one ethylenically unsaturated double bond. In particular, it may be a polyfunctional compound having at least two functional groups from the viewpoint of chemical resistance.

The photopolymerizable compound (B) may be selected from the group consisting of ethylene glycol di(meth)acrylate, propylene glycol di(meth)acrylate, diethylene glycol di(meth)acrylate, triethylene glycol di(meth)acrylate, 1,6-hexanediol di(meth)acrylate, polyethylene glycol di(meth)acrylate, polypropylene glycol di(meth)acrylate, glycerin tri(meth)acrylate, trimethylolpropane tri(meth)acrylate, pentaerythritol tri(meth)acrylate, a monoester of pentaerythritol tri(meth)acrylate and succinic acid, pentaerythritol tetra(meth)acrylate, dipentaerythritol penta(meth)acrylate, dipentaerythritol hexa(meth)acrylate, a monoester of dipentaerythritol penta(meth)acrylate and succinic acid, pentaerythritol triacrylate-hexamethylene diisocyanate (a reaction product of pentaerythritol triacrylate and hexamethylene diisocyanate), trip entaerythritol hepta(meth)acrylate, trip entaerythritol octa(meth)acrylate, bisphenol A epoxyacrylate, ethylene glycol monomethyl ether acrylate, and a mixture thereof, but it is not limited thereto.

Examples of the photopolymerizable compound commercially available may include (i) monofunctional (meth)acrylate such as Aronix M-101, M-111, and M-114 manufactured by Toagosei Co., Ltd., KAYARAD T4-110S and T4-120S manufactured by Nippon Kayaku Co., Ltd., and V-158 and V-2311 manufactured by Osaka Yuki Kayaku Kogyo Co., Ltd.; (ii) bifunctional (meth)acrylate such as Aronix M-210, M-240, and M-6200 manufactured by Toagosei Co., Ltd., KAYARAD HDDA, HX-220, and R-604 manufactured by Nippon Kayaku Co., Ltd., and V-260, V-312, and V-335 HP manufactured by Osaka Yuki Kayaku Kogyo Co., Ltd.; and (iii) tri- and higher functional (meth)acrylate such as Aronix M-309, M-400, M-403, M-405, M-450, M-7100, M-8030, M-8060, and TO-1382 manufactured by Toagosei Co., Ltd., KAYARAD TMPTA, DPHA, and DPHA-40H manufactured by Nippon Kayaku Co., Ltd., and V-295, V-300, V-360, V-GPT, V-3PA, V-400, and V-802 manufactured by Osaka Yuki Kayaku Kogyo Co., Ltd.

The amount of the photopolymerizable compound (B) may be 10 to 90 parts by weight, 40 to 90 parts by weight, 50 to 90 parts by weight, 50 to 80 parts by weight, or 60 to 90 parts by weight, based on 100 parts by weight of the copolymer (A) and/or the copolymer (F) on the basis of the solids content exclusive of solvents. If the amount of the photopolymerizable compound (B) is within the above range, the pattern developability and coating characteristics may be excellent while the film retention rate is maintained to be constant.

(C) Photopolymerization initiator

The photopolymerization initiator (C) employed in the present invention may be any known photopolymerization initiator.

The photopolymerization initiator (C) may be selected from the group consisting of an acetophenone-based compound, a non-imidazole-based compound, a triazine-based compound, an onium salt-based compound, a benzoin-based compound, a benzophenone-based compound, a polynuclear quinone-based compound, a thioxanthone-based compound, a diazo-based compound, an imidesulfonate-based compound, an oxime-based compound, a carbazole-based compound, a sulfonium borate-based compound, a ketone-based compound, and a mixture thereof.

Specifically, an oxime-based compound, a triazine-based compound, or a combination thereof may be used as the photopolymerization initiator (C). More specifically, a combination of an oxime-based compound and a triazine-based compound may be used.

Particular examples of the photopolymerization initiator (C) may include 2,2′-azobis(2,4-dimethylvaleronitrile), 2,2′-azobis(4-methoxy-2,4-dimethylvaleronitrile), benzoyl peroxide, lauryl peroxide, t-butyl peroxy pivalate, 1,1-bis(t-butylperoxy)cyclohexane, p-dimethylaminoacetophenone, 2-benzyl-2-(dimethylamino)-1-[4-(4-morpholinyl)phenyl]-1-butanone, 2-hydroxy-2-methyl-1-phenyl-propan-1-one, benzyl dimethyl ketal, benzophenone, benzoin propyl ether, diethyl thioxanthone, 2,4-bis (trichloromethyl)-6-p-methoxyphenyl-s-triazine, 2-trichloromethyl-5-styryl-1,3,4-oxodiazole, 9-phenylacridine, 3-methyl-5-amino-((s-triazin-2-yl)amino)-3-phenylcoumarin, 2-(o-chlorophenyl)-4,5-diphenylimidazolyl dimer, 1-phenyl-1,2-propanedione-2-(o-ethoxycarbonyl)oxime, 1-[4-(phenylthio)phenyl]-octane-1,2-dione-2-(o-benzoyloxime), o-enzoyl-4′-(benzmercapto)benzoyl-hexyl-ketoxime, 2,4, 6-trimethylphenylcarbonyl-diphenylphosphonyloxide, a hexafluorophosphoro-trialkylphenylsulfonium salt, 2-mercaptobenzimidazole, 2,2′-benzothiazolyl disulfide, 2-[4-(2-phenylethenyl)phenyl]-4, 6-bis(trichloromethyl)-1,3,5-triazine, 2-dimethylamino-2-(4-methylbenzyl)-1-(4-morpholin-4-ylphenyl)-butane-1-one, and a mixture thereof, but is not limited thereto.

For reference, examples of the commercially available oxime-based photopolymerization initiators include OXE-01 (BASF), OXE-02 (BASF), OXE-03 (BASF), N-1919 (ADEKA), NCI-930 (ADEKA), and NCI-831 (ADEKA). Examples of the triazine-based photoinitiator include 2-[4-(2-phenylethenyl)phenyl]-4, 6-bis(trichloromethyl)-1,3,5-triazine (Triazine Y, Tronly) and the like.

The photopolymerization initiator (C) may be employed in an amount of 0.1 to 5 parts by weight or 0.5 to 3 parts by weight, based on 100 parts by weight of the copolymer (A) on the basis of the solids content.

Specifically, an oxime-based compound in an amount of 0.5 to 5 parts by weight, 1 to 5 parts by weight, or 2 to 4 parts by weight and a triazine-based compound in an amount of 0.5 to 5 parts by weight, 1 to 5 parts by weight, 2 to 4 parts by weight, or 2 to 3.5 parts by weight may be employed as the photopolymerization initiator based on 100 parts by weight of the copolymer (A) and/or the copolymer (F).

If an oxime-based compound is employed in an amount within the above range, the development and coating characteristics can be enhanced together with high sensitivity. In addition, if a triazine-based compound is employed in an amount within the above range, a coated film with excellent chemical resistance and taper angles upon the formation of a pattern may be obtained together with high sensitivity.

(D) Colorant

The colored photosensitive resin composition of the present invention may comprise a colorant to impart the light-shielding property thereto. Specifically, the colorant (D) may comprise at least one colorant selected from the group consisting of a black organic colorant, a black inorganic colorant, and a colorant other than black.

The colorant (D) employed in the present invention may be a mixture of two or more inorganic or organic colorants. It preferably has high chromogenicity and high heat resistance.

The colorant (D) may comprise a black colorant and a colorant other than black.

The black colorant may comprise at least one colorant selected from the group consisting of a black organic colorant and a black inorganic colorant. Specifically, the black colorant may comprise a black organic colorant and a black inorganic colorant, a colorant other than black, or a combination thereof.

According to an embodiment, the colorant (D) may comprise a black organic colorant and a black inorganic colorant.

According to an embodiment, the colorant (D) may comprise a black organic colorant and a colorant other than black.

According to an embodiment, the colorant (D) may comprise a black organic colorant, a black inorganic colorant, and a black inorganic colorant.

Any black inorganic colorant, any black organic colorant, and any colorant other than black known in the art may be used. For example, any compounds classified as a pigment in the Color Index (published by The Society of Dyers and Colourists) and any dyes known in the art may be used.

Particular examples of the black organic colorant may be at least one selected from the group consisting of aniline black, lactam black, and perylene black. It is preferable to use Black (e.g., BK-0324, TOKUSHIKI Co. Ltd.) in which lactam black (e.g., Black 582 from BASF) is dispersed from the viewpoint of low reflectance, high light-shielding property, optical density, dielectricity, and the like.

Specifically, the black organic colorant can lower the energy band gap. The lower the energy band gap, the lower the degree of reflection of light. In addition, the black organic colorant can absorb all wavelength ranges in the visible range, which is advantageous for minimizing reflectance.

Particular examples of the black inorganic colorant may include carbon black, titanium black, a metal oxide such as Cu-Fe-Mn-based oxide and synthetic iron black, and the like. It is preferable to use carbon black among them from the viewpoint of pattern characteristics and chemical resistance.

Particular examples of the colorant other than black may include C.I. Pigment Violet 13, 14, 19, 23, 25, 27, 29, 32, 33, 36, 37 38; and C.I. Pigment Blue 15 (15:3, 15:4, 15:6, etc.), 16, 21, 28, 60, 64, and 76. Specifically, the colorant other than black may comprise at least one colorant selected from the group consisting of the blue colorant and the violet colorant. Preferred among them are C.I. Pigment Blue 15:6 and 60, or C.I. Pigment Violet 23 from the viewpoint of lowering the reflectance.

The amount of the colorant (D) may be 20 to 70% by weight, 20 to 60% by weight, 30 to 60% by weight, 30 to 50% by weight or 30 to 45% by weight, based on the total weight of the solids content (i.e., the weight excluding solvents) of the colored photosensitive resin composition. Specifically, the colorant (D) may comprise 40 to 100% by weight or 50 to 100% by weight of a black organic colorant based on the total weight of the solids content (i.e., the weight excluding solvents) of the colorant (D). In addition, the colorant (D) may comprise 0 to 15% by weight, 0 to 10% by weight, 0 to 6% by weight, greater than 0 to 15% by weight, greater than 0 to 10% by weight, greater than 0 to 6% by weight, 0.01 to 15% by weight, 0.01 to 10% by weight or 0.01 to 6% by weight of a black inorganic colorant based on the total weight of the solids content (i.e., the weight excluding solvents) of the colorant (D).

Further, the colorant (D) may comprise 0 to 50% by weight and/or greater than 0 to 50% by weight of a blue colorant and a violet colorant, based on the total weight of the solids content (i.e., the weight excluding solvents) of the colorant (D).

Specifically, the colorant (D) may comprise 0 to 50% by weight, 0 to 40% by weight, 0.01 to 50% by weight, or 0.01 to 40% by weight of a blue colorant and/or 0 to 50% by weight, 0 to 40% by weight, 0.01 to 50% by weight, or 0.01 to 40% by weight of a violet colorant, based on the total weight of the solids content (i.e., the weight excluding solvents) of the colorant (D). Within the above ranges, a pattern profile upon development may be favorable, such properties as film retention rate and optical density may be enhanced, and it is possible to achieve a total reflectance as desired.

The colorant (D) employed in the present invention may be used in a form mixed with a dispersant, a dispersion resin (or a binder), a solvent, and the like in order to disperse the colorant in the colored photosensitive resin composition.

Examples of the dispersant may include any known dispersants for a colorant. Particular examples thereof may include a cationic surfactant, an anionic surfactant, a non-ionic surfactant, a zwitterionic surfactant, a silicon-based surfactant, a fluorine-based surfactant, and the like. Commercially available dispersants may include Disperbyk-182, -183, -184, -185, -2000, -2150, -2155, -2163, and -2164 from BYK Co. They may be used alone or in combination of two or more thereof The dispersant may be added in advance to a colorant through surface treatment of the colorant therewith or added together with a colorant at the time of preparing a colored photosensitive resin composition.

In addition, the colorant (D) may be mixed with a dispersion resin, which may then be used in the production of the colored photosensitive resin composition. In such event, the dispersion resin used may be the copolymer (A) and the copolymer (F) as described herein, a known copolymer, or a mixture thereof.

That is, the colorant (D) may be in the form of a colored dispersion liquid. The colored dispersion liquid may be prepared by mixing the colorant (D), the dispersing resin, and the dispersant at the same time and then milling them. Alternatively, it may be prepared by mixing the colorant (D) and the dispersant in advance as described above, followed by mixing them with the dispersing resin and milling them. Here, the milling is carried out until the average diameter of the raw materials of the colored dispersion liquid becomes 50 to 250 nm, 50 to 150 nm, or 50 to 110 nm. Within the above range, no multilayered structure is formed in the colored dispersion liquid, whereby a more homogeneous colored dispersion liquid can be obtained.

The colored dispersion liquid of the present invention may be employed in an amount of 20 to 70% by weight or 30 to 60% by weight, based on the total weight of the solids content of the colored photosensitive resin composition.

When a light-shielding black matrix obtained from the colored photosensitive resin composition of the present invention, which comprises the colorant (D), is applied to a display, specifically, when a cured film having a thickness of 3 μm formed from the photosensitive resin composition is measured by the SCI method at a wavelength of 360 to 740 nm, it shows a total reflectance of 4.8% or less, 4.7% or less, 4.6% or less, 4.0 to 4.8%, 4.0 to 4.7%, or 4.0 to 4.6%. Thus, it is possible to satisfy the characteristics of low reflectance and high light-shielding property and/or to prevent the light leakage phenomenon of red or green color (see Evaluation Example 1).

(E) Surfactant

The colored photosensitive resin composition of the present invention may further comprise a surfactant (E) in order to enhance coatability and to prevent the generation of defects.

Although the kind of the surfactant (E) is not particularly limited, for example, a fluorine-based surfactant or silicon-based surfactant may be used.

The commercially available silicon-based surfactant may include DC3PA, DC7PA, SH11PA, SH21PA, and SH8400 from Dow Corning Toray Silicon, TSF-4440, TSF-4300, TSF-4445, TSF-4446, TSF-4460, and TSF-4452 from GE Toshiba Silicone, BYK-333, BYK-307, BYK-3560, BYK UV-3535, BYK-361N, BYK-354, and BYK-399 from BYK, and the like. They may be used alone or in combination of two or more thereof.

The commercially available fluorine-based surfactant may include Megaface F-470, F-471, F-475, F-482, F-489, and F-563 from Dainippon Ink Kagaku Kogyo Co. (DIC).

Preferred among these surfactants may be BYK-333 and BYK-307 from BYK and F-563 from DIC from the viewpoint of coatability of the composition.

The amount of the surfactant (E) may be 0.01 to 3% by weight or 0.1 to 1% by weight, based on the total weight of the solids content (i.e., the weight excluding solvents) of the colored photosensitive resin composition. If the amount of the surfactant is within the above range, the colored photosensitive resin composition may be smoothly coated.

(F) Copolymer

The colored photosensitive resin composition of the present invention may comprise a copolymer (F) different from the copolymer (A).

Specifically, the copolymer (F) may comprise (f-1) a structural unit derived from an ethylenically unsaturated carboxylic acid, an ethylenically unsaturated carboxylic anhydride, or a combination thereof; (f-2) a structural unit derived from a C3-20 aliphatic cyclic ethylenically unsaturated compound; (f-3) a structural unit derived from a C3-20 aliphatic linear ethylenically unsaturated compound; and (f-4) a structural unit derived from an ethylenically unsaturated compound different from (f-1), (f-2), and (f-3). Further, it may further comprise (f-5) a structural unit derived from an ethylenically unsaturated compound containing an epoxy group. Hereinafter, each structural unit will be explained in detail.

(f-1) Structural unit derived from an ethylenically unsaturated carboxylic acid, an ethylenically unsaturated carboxylic anhydride, or a combination thereof

The structural unit (f-1) is derived from an ethylenically unsaturated carboxylic acid, an ethylenically unsaturated carboxylic anhydride, or a combination thereof The ethylenically unsaturated carboxylic acid and the ethylenically unsaturated carboxylic anhydride is a polymerizable unsaturated monomer containing at least one carboxyl group in the molecule. Particular examples thereof may include an unsaturated monocarboxylic acid such as (meth)acrylic acid, crotonic acid, alpha-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; an unsaturated polycarboxylic acid of trivalence or more and an anhydride thereof; and a mono[(meth)acryloyloxyalkyl] ester of a polycarboxylic acid of divalence or more such as mono[2-(meth)acryloyloxyethyl] succinate, mono[2-(meth)acryloyloxyethyl] phthalate, and the like. The structural unit derived from the above-exemplified compounds may be comprised in the copolymer alone or in combination of two or more.

The amount of the structural unit (f-1) may be 5 to 65% by mole, 5 to 50% by mole, 10 to 50% by mole, 5 to 40% by mole, 5 to 30% by mole, or 5 to 20% by mole, based on the total moles of the structural units constituting the copolymer (F). Within the above range, it may have favorable developability.

(f-2) Structural unit derived from a C₃₋₂₀ aliphatic cyclic ethylenically unsaturated compound

The structural unit (f-2) is derived from a C3-20 aliphatic cyclic ethylenically unsaturated compound. The structural unit (f-2) may be derived from a monomer containing a cycloalkyl group. For example, the structural unit (f-2) may be derived from at least one compound selected from the group consisting of cyclohexyl (meth)acrylate, cyclohexylmethyl (meth)acrylate, cyclohexylethyl (meth)acrylate, cyclohexylpropyl (meth)acrylate, cyclohexylbutyl (meth)acrylate, 4-methylcyclohexylmethyl (meth)acrylate, 4-ethylcyclohexylmethyl (meth)acrylate, cyclopentyl (meth)acrylate, and 4-hydroxymethylcyclohexylmethyl (meth)acrylate.

Specifically, it may be derived from at least one compound selected from the group consisting of cyclohexyl (meth)acrylate, cyclohexylmethyl (meth)acrylate, and 4-methylcyclohexylmethyl (meth)acrylate.

The amount of the structural unit (f-2) may be 10 to 30% by mole, 10 to 28% by mole, 12 to 30% by mole, 12 to 29% by mole, 12 to 28% by mole, or 12 to 25% by mole, based on the total moles of the structural units constituting the copolymer (F). Within the above range, it may have a favorable leveling property.

(f-3) Structural unit derived from a C₃₋₂₀ aliphatic linear ethylenically unsaturated compound

The structural unit (a-3) is derived from a C3-20 aliphatic linear ethylenically unsaturated compound. For example, the structural unit (f-3) may be derived from at least one compound selected from the group consisting of propyl (meth)acrylate, butyl (meth)acrylate, pentyl (meth)acrylate, hexyl (meth)acrylate, heptyl (meth)acrylate, octyl (meth)acrylate, nonyl (meth)acrylate, decyl (meth)acrylate, lauryl (meth)acrylate, and dodecyl (meth)acrylate.

The amount of the structural unit (f-3) may be 20 to 50% by mole, 20 to 40% by mole, 30 to 40% by mole, or 32 to 40% by mole, based on the total moles of the structural units constituting the copolymer (F). Within the above range, it may have a favorable leveling property.

(f-4) Structural unit derived from an ethylenically unsaturated compound different from (f-1), (f-2), and (f-3)

The copolymer (F) employed in the present invention may further comprise a structural unit derived from an ethylenically unsaturated compound different from (f-1), (f-2), and (f-3) in addition to (f-1), (f-2), and (f-3).

Particular examples of the structural unit derived from an ethylenically unsaturated compound different from the structural units (f-1), (f-2), and (f-3) may include an unsaturated carboxylic acid ester such as methyl (meth)acrylate, ethyl (meth)acrylate, dimethylaminoethyl (meth)acrylate, isobutyl (meth)acrylate, t-butyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3 -chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; a tertiary amine containing an N-vinyl group such as N-vinyl pyrrolidone, N-vinyl carbazole, and N-vinyl morpholine; an unsaturated ether such as vinyl methyl ether and vinyl ethyl ether; an unsaturated imide such as N-phenylmaleimide, N-(4-chlorophenyl)maleimide, N-(4-hydroxyphenyl)maleimide, N-cyclohexylmaleimide, and the like. The structural unit derived from the above-exemplified compounds may be comprised in the copolymer alone or in combination of two or more. A structural unit derived from unsaturated carboxylic esters among the above is more preferable from the viewpoint of copolymerizability and enhancements in the leveling property.

The amount of the structural unit (f-4) may be 10 to 50% by mole, 10 to 40% by mole, 10 to 30% by mole, 10 to 25% by mole, 15 to 30% by mole, or 15 to 25% by mole, based on the total moles of the structural units constituting the copolymer (F). Within the above range, the storage stability of the colored photosensitive resin composition may be maintained, and the film retention rate may be more advantageously enhanced.

(f-5) Structural unit derived from an ethylenically unsaturated compound containing an epoxy group

The copolymer (F) may further comprise (f-5) a structural unit derived from an ethylenically unsaturated compound containing an epoxy group in addition to the structural units as described above.

The structural unit (f-5) is derived from an ethylenically unsaturated compound containing an epoxy group. Particular examples of the ethylenically unsaturated compound containing an epoxy group may include glycidyl (meth)acrylate, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, a-ethyl glycidyl acrylate, a-n-propyl glycidyl acrylate, a-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, 4-hydroxybutyl (meth)acrylate glycidyl ether, allyl glycidyl ether, 2-methylallyl glycidyl ether, and the like. The structural unit derived from the above-exemplified compounds may be comprised in the copolymer alone or in combination of two or more. A structural unit derived from glycidyl (meth)acrylate and/or 4-hydroxybutyl (meth)acrylate glycidyl ether among the above is more preferable from the viewpoint of copolymerizability and enhancements in the strength of a cured film.

The amount of the structural unit (f-5) may be 1 to 40% by mole or 5 to 20% by mole, based on the total moles of the structural units constituting the copolymer (F). Within the above range, it may be more advantageous in terms of residues during the process and margins upon pre-bake.

Examples of the copolymer having the above structural units (f-1) to (f-4) and/or (f-1) to (f-5) include (meth)acrylic acid/cyclohexyl (meth)acrylate/butyl (meth)acrylate/methyl (meth)acrylate, (meth)acrylic acid/cyclohexyl (meth)acrylate/butyl (meth)acrylate/methyl (meth)acrylate/glycidyl (meth)acrylate, (meth)acrylic acid/cyclohexyl (meth)acrylate/butyl (meth)acrylate/methyl (meth)acrylate/4-hydroxybutyl (meth)acrylate glycidyl ether, (meth)acrylic acid/cyclohexyl (meth)acrylate/butyl (meth)acrylate/methyl (meth)acrylate/3,4-epoxycyclohexyl (meth)acrylate, (meth)acrylic acid/cyclohexyl (meth)acrylate/pentyl (meth)acrylate/methyl (meth)acrylate/glycidyl (meth)acrylate, (meth)acrylic acid/cyclohexyl (meth)acrylate/pentyl (meth)acrylate/methyl (meth)acrylate/3,4-epoxycyclohexyl (meth)acrylate, (meth)acrylic acid/cyclohexyl (meth)acrylate/hexyl (meth)acrylate/methyl (meth)acrylate/glycidyl (meth)acrylate, (meth)acrylic acid/cyclohexyl (meth)acrylate/hexyl (meth)acrylate/methyl (meth)acrylate/3,4-epoxycyclohexyl (meth)acrylate.

One, two, or more of the copolymers may be comprised in the colored photosensitive resin composition.

The weight average molecular weight of the copolymer (F) may be 3,000 to 10,000 Da, 3,000 to 9,500 Da, 3,000 to 9,000 Da, 4,000 to 9,000 Da, 4,000 to 8,000 Da, or 4,000 to 7,000 Da. If the weight average molecular weight of the copolymer is within the above range, the step difference by a lower pattern may be advantageously improved, and the leveling property and a pattern profile upon development may be favorable.

The amount of the copolymer (F) in the colored photosensitive resin composition may be 5 to 40% by weight, 5 to 30% by weight, 10 to 40% by weight, or 10 to 30% by weight, based on the total weight of the solids content, exclusive of solvents, in the colored photosensitive resin composition. Within the above range, the leveling property is excellent, a pattern profile upon development may be favorable, and such properties as film retention rate and chemical resistance may be improved.

The copolymer (F) may be prepared by charging to a reactor a radical polymerization initiator, a solvent, and the above structural units, followed by charging nitrogen thereto and slowly stirring the mixture for polymerization.

The radical polymerization initiator may be an azo compound such as 2,2′-azobisisobutyronitrile, 2,2′-azobis(2,4-dimethylvaleronitrile), and 2,2′-azobis(4-methoxy-2,4-dimethylvaleronitrile); or benzoyl peroxide, lauryl peroxide, t-butyl peroxypivalate, 1,1-bis(t-butylperoxy)cyclohexane, or the like, but is not limited thereto. The radical polymerization initiator may be used alone or in combination of two or more.

The solvent may be any conventional solvent commonly used in the preparation of a copolymer and may include, for example, propylene glycol monomethyl ether acetate (PGMEA).

(G) Solvent

The colored photosensitive resin composition of the present invention may preferably be prepared as a liquid composition in which the above components are mixed with a solvent. Any solvent known in the art, which is compatible but not reactive with the components in the colored photosensitive resin composition, may be used in the preparation of the colored photosensitive resin composition.

Examples of the solvent may include glycol ethers such as ethylene glycol monoethyl ether; ethylene glycol alkyl ether acetates such as ethyl cellosolve acetate; esters such as ethyl 2-hydroxypropionate; diethylene glycols such as diethylene glycol monomethyl ether; propylene glycol alkyl ether acetates such as propylene glycol monomethyl ether acetate and propylene glycol propyl ether acetate; and alkoxyalkyl acetates such as 3-methoxybutyl acetate. The solvent may be used alone or in combination of two or more.

The amount of the solvent is not specifically limited, but may be 50 to 90% by weight, or 70 to 85% by weight, based on the total weight of the colored photosensitive resin composition finally prepared from the viewpoint of coatability and stability of the colored photosensitive resin composition finally obtained. If the amount of the solvent is within the above range, the resin composition is smoothly coated, and the delay margin, which may occur in the working process, is small.

In addition, the colored photosensitive resin composition of the present invention may comprise other additives such as an antioxidant and a stabilizer as long as the physical properties of the colored photosensitive resin composition are not adversely affected.

A cured film formed from the colored photosensitive resin composition may have an optical density of 0.6/μm to 2.0/μm or 0.6/μm to 1.5/μm. If the optical density per 1 μm in thickness of a cured film formed from the colored photosensitive resin composition is within the above range, the resolution of a display screen is enhanced. In addition, since the colored photosensitive resin composition of the present invention is excellent in leveling property, it can form a flat film even on a substrate having irregularities. Further, even when a filter is further attached to the cured film, the film deviation of the filter is maintained the same as the cured film, thereby forming a flat filter film.

As such, the cured film (and the filter) that maintains a constant thickness without a film deviation can maintain the light path to be constant (i.e., the brightness is kept constant), thereby preventing the occurrence of visible stains to further improve the optical properties (e.g., visibility).

The colored photosensitive resin composition of the present invention comprising the above-described components may be prepared by a common method, for example, by the following method.

At first, a colorant is mixed with a dispersion resin, a dispersant, and a solvent in advance and dispersed therein using a bead mill until the average particle diameter of the colorant reaches a desired value, thereby preparing a colored dispersion liquid. In such event, a surfactant and/or a copolymer may be blended in part or in entirety. Added to the dispersion liquid are the remainder of the copolymer and the surfactant, a photopolymerizable compound, and a photopolymerization initiator. An additive such as an epoxy compound or an additional solvent, if necessary, is further blended to a certain concentration, followed by sufficiently stirring them to obtain a desired colored photosensitive resin composition.

The present invention also provides a light-shielding black matrix prepared from the colored photosensitive resin composition.

The light-shielding black matrix may be prepared by a coating formation step, a light exposure step, a development step, and a heating step.

In the coating formation step, the colored photosensitive resin composition according to the present invention is coated on a pre-treated substrate by a spin coating method, a slit coating method, a roll coating method, a screen printing method, an applicator method, or the like in a desired thickness, for example, 1 to 25 μm, which is then pre-cured at a temperature of 70 to 100° C. for 1 to 10 minutes to form a coated film by removing the solvent therefrom.

In order to form a pattern on the coated film, a mask having a predetermined shape is placed thereon, which is then irradiated with activated rays of 200 to 500 nm. As a light source used for the irradiation, a low-pressure mercury lamp, a high-pressure mercury lamp, an extra high-pressure mercury lamp, a metal halide lamp, an argon gas laser, or the like may be used. X-ray, electronic ray, or the like may also be used, if desired. The rate of light exposure may vary depending on the kind and the compositional ratio of the components of the composition and the thickness of a dried coating. If a high-pressure mercury lamp is used, the rate of light exposure may be 500 mJ/cm² or less (at the wavelength of 365 nm).

After the light exposure step, an aqueous alkaline solution such as sodium carbonate, sodium hydroxide, potassium hydroxide, tetramethylammonium hydroxide, or the like as a developer is used to dissolve and remove unnecessary portions, whereby only an exposed portion remains to form a pattern. An image pattern obtained by the development is cooled to room temperature and post-baked in a hot air circulation-type drying furnace at a temperature of 180 to 250° C. for 10 to 60 minutes, thereby obtaining a final pattern.

Since the light-shielding black matrix thus prepared has excellent properties, it can be advantageously used in an electronic device for liquid crystal displays and quantum dot displays. Thus, the present invention provides an electronic device comprising the light-shielding black matrix.

The liquid crystal displays and quantum dot displays may comprise other components known to those skilled in the art, except that they are provided with the light-shielding black matrix of the present invention. That is, the liquid crystal displays and quantum dot displays, to which the light-shielding black matrix of the present invention can be applied, may fall within the scope of the present invention.

Hereinafter, the present invention will be described in more detail with reference to the following examples. However, these examples are provided to illustrate the present invention, and the scope of the present invention is not limited thereto only.

In the following preparation examples, the weight average molecular weight is determined by gel permeation chromatography (GPC, eluent: tetrahydrofuran) referenced to a polystyrene standard.

Preparation Example 1: Preparation of a copolymer (A)

A 500-ml, round-bottomed flask equipped with a refluxing condenser and a stirrer was charged with 100 g of a monomer mixture consisting of 50% by mole of N-phenylmaleimide (PMI), 6% by mole of styrene, 10% by mole of 4-hydroxybutyl acrylate glycidyl ether (4-HBAGE), and 34% by mole of methacrylic acid (MAA), along with 300 g of propylene glycol monomethyl ether acetate (PGMEA) as a solvent and 2 g of 2,2′-azobis(2,4-dimethylvaleronitrile) as a radical polymerization initiator. Thereafter, the mixture was heated to 70° C. and stirred for 5 hours to obtain a copolymer (A) solution having a solids content of 31% by weight. The copolymer thus prepared had an acid value of 100 mg KOH/g and a weight average molecular weight (Mw) of 7,000 Da.

Preparation Example 2: Preparation of a copolymer (F)

A copolymer (F) was prepared in the same manner as in Preparation Example 1, except that 100 g of a monomer mixture consisting of 21% by mole of cyclohexyl methacrylate (CHMA), 10% by mole of glycidyl methacrylate (GMA), 32% by mole of butyl methacrylate (BMA), 17% by mole of methacrylic acid (MAA), and 20% by mole of methyl methacrylate (MMA) was used. The copolymer (F) thus prepared had an acid value of 600 mg KOH/g and a weight average molecular weight (Mw) of 4,700 Da.

Examples and Comparative Examples: Preparation of colored photosensitive resin compositions

The colored photosensitive resin compositions of the following Examples and Comparative Examples were each prepared using the compounds prepared in the above Preparation Examples.

The components used in the following Examples and Comparative Examples are as follows.

TABLE 1

| | | | | Solids |
|---|---|---|---|---|
| | | | | content |
| | | | | (% by |
| Component* | | Compound name and/or brand name | Manufacturer | weight) |
| Copolymer (A) | | Prep. Ex. 1 | — | 31 |
| PC (B) | | Dipentaerythritol hexaacrylate (DPHA) | Nippon | 100 |
| | | | Kayaku | |
| PI | C-1 | N-1919 (oxime-based photoinitiator) | ADEKA | 100 |
| (C) | C-2 | 2-[4-(2-phenylethenyl)phenyl]-4,6-bis(trichloromethyl)- | Tronly | 100 |
| | | 1,3,5-triazine (Triazine Y, triazine-based photoinitiator) | | |
| Colorant | D-1 | BK-0326 (comprising carbon black) | TOKUSHI | 100 |
| (D) | | | KI Co., LTD | |
| | D-2 | BK-0324 (comprising organic black) | TOKUSHI | 100 |
| | | | KI Co., LTD | |
| | D-3 | Blue-B2 (comprising Pigment Blue 15:6) | Iridos Co. | 100 |
| | | | Ltd. | |
| | D-4 | IV-005 (comprising Pigment Violet 23) | Iridos Co. | 100 |
| | | | Ltd. | |
| | D-5 | PR254-1 (comprising Pigment Red 254) | Iridos Co. | 100 |
| | | | Ltd. | |
| | D-6 | PY139-2 (comprising Pigment Yellow 139) | Iridos Co. | 100 |
| | | | Ltd. | |
| | D-7 | DS-02 (comprising silica sol, SiO₂ average diameter | Iridos Co. | 100 |
| | | 89.4 nm) | Ltd. | |

| | | | |
|---|---|---|---|
| Surfactant (E) | BYK-307 | BYK | 100 |
| Copolymer (F) | Prep. Ex. 2 | — | 31 |
| Solvent (G) | Propylene glycol monomethyl ether acetate (PGMEA) | Chemtronics | — |

*PC: photopolymerizable compound; PI: photopolymerization initiator

### Example 1

100 parts by weight of the copolymer (A) of Preparation Example 1, 80 parts by weight of DPHA as the photopolymerizable compound (B), 3.7 parts by weight of the oxime-based photopolymerization initiator N-1919 and 3.1 parts by weight of the triazine-based photopolymerization initiator Triazine-Y as the photopolymerization initiator (C), 123.9 parts by weight of BK-0324 as the colorant (D), and 0.2 part by weight of BYK-307 as the surfactant (E) were homogeneously mixed. Here, the respective contents are those based on the solids content exclusive of the solvent. The mixture was dissolved in PGMEA such that that the solids content of the mixture was 19% by weight. The resultant was mixed for 2 hours to prepare a liquid-phase colored photosensitive resin composition.

### Examples 2 to 9 and Comparative Examples 1 to 5

Liquid-phase colored photosensitive resin compositions were each prepared in the same manner as in Example 1, except that the kinds and/or the contents of the respective components were changed as shown in Table 2 below.

TABLE 2

| (part by | Copolymer | PC* | PI* (C) | | Colorant (D) | | | | | | | S* |
|---|---|---|---|---|---|---|---|---|---|---|---|---|
| weight) | (A) | (B) | C-1 | C-2 | D-1 | D-2 | D-3 | D-4 | D-5 | D-6 | D-7 | (E) |
| Ex. 1 | 100 | 80 | 3.7 | 3.1 | 0 | 123.9 | 0 | 0 | 0 | 0 | 0 | 0.2 |
| Ex. 2 | 100 | 80 | 3.2 | 2.7 | 0 | 79.6 | 0 | 0 | 0 | 0 | 0 | 0.2 |
| Ex. 3 | 100 | 80 | 3.7 | 3.1 | 0 | 61.9 | 61.9 | 0 | 0 | 0 | 0 | 0.2 |
| Ex. 4 | 100 | 80 | 3.7 | 3.1 | 0 | 61.9 | 31 | 0 | 0 | 0 | 0 | 0.2 |
| Ex. 5 | 100 | 80 | 3.7 | 3.1 | 3.7 | 85.5 | 34.7 | 0 | 0 | 0 | 0 | 0.2 |
| Ex. 6 | 100 | 80 | 3.7 | 3.1 | 6.2 | 84.2 | 33.5 | 0 | 0 | 0 | 0 | 0.2 |
| Ex. 7 | 100 | 80 | 3.7 | 3.1 | 9.9 | 81.8 | 32.2 | 0 | 0 | 0 | 0 | 0.2 |
| Ex. 8 | 100 | 80 | 3.7 | 3.1 | 12.4 | 79.3 | 32.2 | 0 | 0 | 0 | 0 | 0.2 |
| Ex. 9 | 100 | 80 | 3.7 | 3.1 | 6.2 | 80.5 | 33.5 | 3.7 | 0 | 0 | 0 | 0.2 |
| C. Ex. 1 | 100 | 80 | 3.7 | 3.1 | 0 | 61.9 | 0 | 0 | 61.9 | 0 | 0 | 0.2 |
| C. Ex. 2 | 100 | 80 | 3.7 | 3.1 | 0 | 61.9 | 0 | 0 | 0 | 61.9 | 0 | 0.2 |
| C. Ex. 3 | 100 | 80 | 3.7 | 3.1 | 0 | 123.9 | 0 | 0 | 0 | 0 | 0 | 0.2 |
| C. Ex. 4 | 100 | 70 | 4.3 | 3.6 | 142.4 | 0 | 0 | 0 | 0 | 0 | 35.6 | 0.2 |
| C. Ex. 5 | 100 | 70 | 5.4 | 4.5 | 181.0 | 0 | 0 | 0 | 0 | 0 | 89.2 | 0.2 |

*PC: photopolymerizable compound; PI: photopolymerization initiator; S: surfactant

### Examples 10 to 17 and Comparative Examples 6 to 8

Liquid-phase colored photosensitive resin compositions were each prepared in Examples 10 to 17 and Comparative Examples 6 to 8 in a manner corresponding to Examples 1 to 3 and Examples 5 to 9 and Comparative Examples 2, 3 and 5, except that 50 parts by weight of the copolymer (A) of Preparation Example 1 and 50 parts by weight of the copolymer (F) of Preparation Example 2 were used as the copolymer.

TABLE 3

| (part by | CP* | CP* | PC* | PI* (C) | | Colorant (D) | | | | | | | S* |
|---|---|---|---|---|---|---|---|---|---|---|---|---|---|
| weight) | (A) | (F) | (B) | C-1 | C-2 | D-1 | D-2 | D-3 | D-4 | D-5 | D-6 | D-7 | (E) |
| Ex. 10 | 50 | 50 | 80 | 3.7 | 3.1 | 0 | 123.9 | 0 | 0 | 0 | 0 | 0 | 0.2 |
| Ex. 11 | 50 | 50 | 80 | 3.2 | 2.7 | 0 | 79.6 | 0 | 0 | 0 | 0 | 0 | 0.2 |
| Ex. 12 | 50 | 50 | 80 | 3.7 | 3.1 | 0 | 61.9 | 61.9 | 0 | 0 | 0 | 0 | 0.2 |
| Ex. 13 | 50 | 50 | 80 | 3.7 | 3.1 | 3.7 | 85.5 | 34.7 | 0 | 0 | 0 | 0 | 0.2 |
| Ex. 14 | 50 | 50 | 80 | 3.7 | 3.1 | 6.2 | 84.2 | 33.5 | 0 | 0 | 0 | 0 | 0.2 |
| Ex. 15 | 50 | 50 | 80 | 3.7 | 3.1 | 9.9 | 81.8 | 32.2 | 0 | 0 | 0 | 0 | 0.2 |
| Ex. 16 | 50 | 50 | 80 | 3.7 | 3.1 | 12.4 | 79.3 | 32.2 | 0 | 0 | 0 | 0 | 0.2 |
| Ex. 17 | 50 | 50 | 80 | 3.7 | 3.1 | 6.2 | 80.5 | 33.5 | 3.7 | 0 | 0 | 0 | 0.2 |
| C. Ex. 6 | 50 | 50 | 80 | 3.7 | 3.1 | 0 | 61.9 | 0 | 0 | 0 | 61.9 | 0 | 0.2 |
| C. Ex. 7 | 50 | 50 | 80 | 3.7 | 3.1 | 0 | 123.9 | 0 | 0 | 0 | 0 | 0 | 0.2 |
| C. Ex. 8 | 50 | 50 | 70 | 5.4 | 4.5 | 181.0 | 0 | 0 | 0 | 0 | 0 | 89.2 | 0.2 |

*CP: copolymer; PC: photopolymerizable compound; PI: photopolymerization initiator; S: surfactant

### Evaluation Example 1: Reflectance

The colored photosensitive resin compositions obtained in the Examples and in Comparative Examples were each coated on a glass substrate using a spin coater and pre-baked at 95° C. for 150 seconds to form a coated film in a thickness of 3.8 μm. A mask was placed on the coated film thus formed such that an area of 5 cm by 5 cm of the coated film was 100% exposed to light and that the gap with the substrate was maintained at 250 μm. Thereafter, the film was exposed to light at an exposure rate of 0 to 300 mJ/cm² based on a wavelength of 365 nm for a certain time period using an aligner (model name: MA6) that emits light having a wavelength of 200 nm to 450 nm. Thereafter, it was then developed at 23° C. with an aqueous solution of 0.04% by weight of potassium hydroxide (i.e., a developer) until the unexposed portion was completely washed out. Then, the pattern thus formed was post-baked in an oven at 230° C. for 30 minutes to obtain a cured film in a thickness of 3.0 μm (±less than 0 3μm).

The cured film was measured for the total reflectance (specular component included; SCI) and the scattered reflectance (specular component excluded; SCE) using a spectrophotometer device (CM-3700A). The specular reflectance was obtained as the difference between the total reflectance and the scattered reflectance.

When the total reflectance was 4.6% or less, it was evaluated as o. If it exceeded 4.6%, it was evaluated as ×.

### Evaluation Example 2: Optical density

A cured film having a thickness of 3.0 (±0.3) μm after post-bake was obtained in the same manner as in Evaluation Example 1, except that a mask was not employed in the process for the preparation of a cured film of Evaluation Example 1. The transmittance at 550 nm of the cured film was measured using an optical density meter (361T manufactured by Xlite), and the optical density (OD, unit: /μm) based on a thickness of 1 μm was determined.

### Evaluation Example 3: Development time

At the time of development with an aqueous solution of 0.04% by weight of potassium hydroxide (i.e., a developer) in the process for the preparation of a cured film of Evaluation Example 1, the time for which the unexposed portion was completely washed out (until the stage O-ring part of the development apparatus was completely seen behind the substrate) was measured.

When the development time was 100 seconds or less, it was evaluated as o. If it exceeded 100 seconds, it was evaluated as ×.

### Evaluation Example 4: Evaluation of resolution

A cured film was obtained in the same manner as in Evaluation Example 1. In order to measure the resolution of the pattern in the cured film thus obtained, the minimum size of the pattern was observed with a micro-optical microscope (STM6-LM, manufacturer: OLYMPUS). That is, the minimum pattern dimension after curing was measured at the optimum exposure dose when the line width (CD; critical dimension, unit: μm) of the 20-μm patterned line pattern was less than 30 μm. If the line width was 10 μm or more less than 30 μm, it was evaluated as o. If it exceeded 30 μm or was less than 10 μm, it was evaluated as ×.

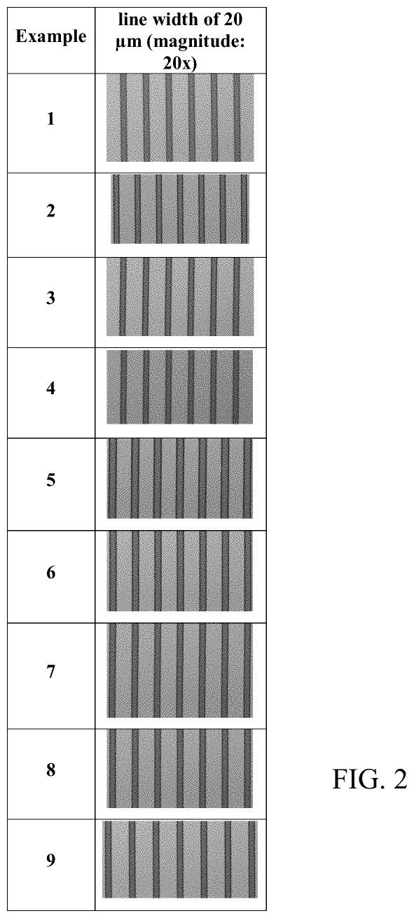

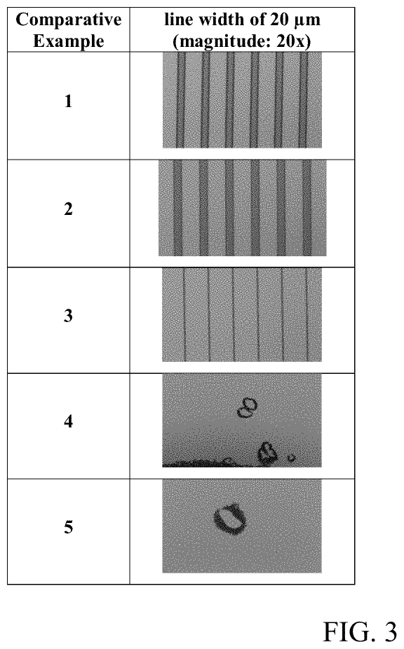

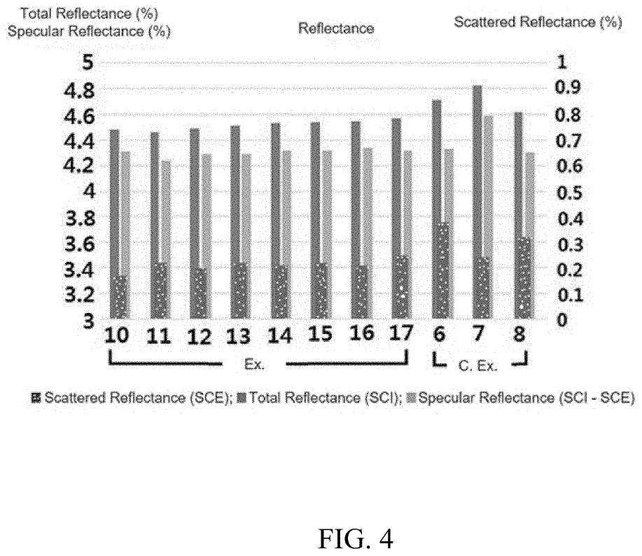

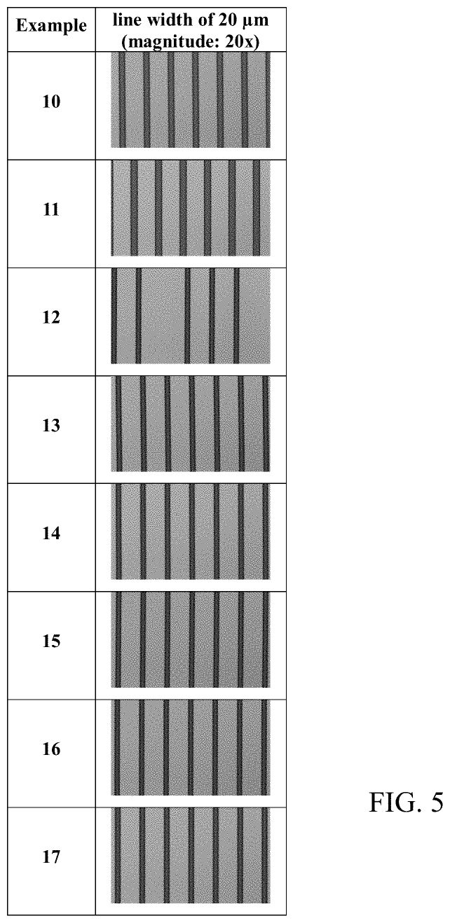

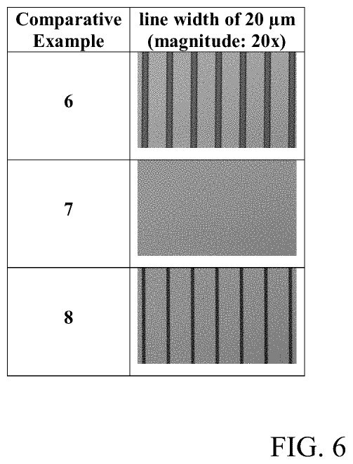

In addition, a cured film was obtained in the same manner as in Evaluation Example 1, except that a mask having a pattern of lines in a size ranging from 5 μm to 20 μm, wherein the same pattern array, was used in the process for the preparation of a cured film of Evaluation Example 1. The surface of the cured film was observed with a micro-optical microscope to confirm whether a line width (CD; critical dimension, unit: μm) of 20 μm was realized. The results are shown in FIGS. 2, 3, 5, and 6 as photographs.

### Evaluation Example 5: Thickness of a cured film

The cured film thus prepared was measured for the height difference through the vertical motion of the equipment probe tip using SCAN PLUS, which is an a-step instrument (Alpha-step profilometer). The thickness of the cured film was obtained from the results.

Evaluation Example 6: Leveling property A cured film was obtained in the same manner as in Evaluation Example 1, except that the compositions of Examples 1, 2, 10, and 11 were each coated on a substrate on which ribs (or rectangular irregularities) had been formed.

The cross-section of the substrate on which the cured film had been formed was imaged with an electron scanning microscope (SEM).

The thickness of the ribs \textcircled{1}, the thickness of the cured film \textcircled{2} located on the top of the ribs, and the thickness of the cured film \textcircled{3} in the rib-free portion were measured. The smaller the height difference \textcircled{4} according to the following equation, the more excellent the leveling property. The results are shown in Table 6 below and FIG. 9.

[Equation 1]

(Thickness of ribs+thickness of the cured film located on the top of ribs)−thickness of the cured film in the rib-free portion

TABLE 4

| | | | | Specular | | | | | | |
|---|---|---|---|---|---|---|---|---|---|---|
| | Total | | Scattered | reflectance | Optical | | | | | Film |
| | reflectance | | reflectance | (SCI − | density | Development | | Resolution | | thickness |
| | (SCI, %) | | (SCE, %) | SCE, %) | (/μm) | time (second) | | (μm) | | (μm) |
| Ex. 1 | 4.55 | ∘ | 0.18 | 4.37 | 1.15 | 50 | ∘ | 28 | ∘ | 2.85 |
| Ex. 2 | 4.49 | ∘ | 0.21 | 4.28 | 0.85 | 55 | ∘ | 29 | ∘ | 3.06 |
| Ex. 3 | 4.52 | ∘ | 0.16 | 4.36 | 0.69 | 80 | ∘ | 27 | ∘ | 2.91 |
| Ex. 4 | 4.51 | ∘ | 0.13 | 4.38 | 0.76 | 90 | ∘ | 27 | ∘ | 3.11 |
| Ex. 5 | 4.40 | ∘ | 0.15 | 4.25 | 0.91 | 72 | ∘ | 26 | ∘ | 2.90 |
| Ex. 6 | 4.40 | ∘ | 0.16 | 4.24 | 0.93 | 74 | ∘ | 24 | ∘ | 3.03 |
| Ex. 7 | 4.40 | ∘ | 0.17 | 4.23 | 0.93 | 73 | ∘ | 23 | ∘ | 3.09 |
| Ex. 8 | 4.43 | ∘ | 0.18 | 4.25 | 0.93 | 74 | ∘ | 23 | ∘ | 3.16 |
| Ex. 9 | 4.49 | ∘ | 0.19 | 4.3 | 0.80 | 82 | ∘ | 24 | ∘ | 2.94 |
| C. Ex. 1 | 4.99 | x | 0.57 | 4.42 | 0.97 | 130 | x | 37 | x | 2.86 |
| C. Ex. 2 | 6.12 | x | 1.67 | 4.45 | 0.81 | 45 | ∘ | 32 | x | 2.92 |
| C. Ex. 3 | 4.83 | x | 0.24 | 4.59 | 1.66 | 49 | ∘ | 7 | x | 3.23 |
| C. Ex. 4 | 5.00 | x | 0.25 | 4.75 | 1.54 | 35 | ∘ | N/A | x | 2.52 |
| C. Ex. 5 | 5.05 | x | 0.32 | 4.73 | 1.68 | 23 | ∘ | N/A | x | 2.33 |

TABLE 5

| | | | | Specular | | | | |
|---|---|---|---|---|---|---|---|---|
| | Total | | Scattered | reflectance | Optical | | | Film |
| | reflectance | | reflectance | (SCI − | density | Development | | thickness |
| | (SCI, %) | | (SCE, %) | SCE, %) | (/μm) | time (second) | | (μm) |
| Ex. 10 | 4.48 | ∘ | 0.17 | 4.31 | 1.13 | 52 | ∘ | 3.19 |
| Ex. 11 | 4.46 | ∘ | 0.22 | 4.24 | 0.84 | 41 | ∘ | 3.14 |
| Ex. 12 | 4.49 | ∘ | 0.2 | 4.29 | 0.69 | 59 | ∘ | 3.21 |
| Ex. 13 | 4.51 | ∘ | 0.22 | 4.29 | 0.96 | 58 | ∘ | 3.15 |
| Ex. 14 | 4.53 | ∘ | 0.21 | 4.32 | 0.97 | 56 | ∘ | 3.17 |
| Ex. 15 | 4.54 | ∘ | 0.22 | 4.32 | 0.99 | 56 | ∘ | 3.14 |
| Ex. 16 | 4.55 | ∘ | 0.21 | 4.34 | 1.03 | 55 | ∘ | 3.08 |
| Ex. 17 | 4.57 | ∘ | 0.25 | 4.32 | 1.04 | 41 | ∘ | 3.17 |
| C. Ex. 6 | 4.71 | x | 0.38 | 4.33 | 0.66 | 22 | ∘ | 3.03 |
| C. Ex. 7 | 4.83 | x | 0.24 | 4.59 | 1.66 | 39 | ∘ | 3.12 |
| C. Ex. 8 | 4.62 | x | 0.32 | 4.30 | 1.28 | 28 | ∘ | 3.04 |

TABLE 6

| (μm) | Ex. 1 | Ex. 2 | Ex. 10 | Ex. 11 |
|---|---|---|---|---|
| Thickness of ribs(\textcircled{1}) | 10.75 | 11.02 | 11.48 | 10.75 |
| Thickness of cured film located | 2.5 | 2.04 | 2.57 | 2.17 |
| on the top of ribs (\textcircled{2}) | | | | |
| Thickness of cured film in the | 9.37 | 9.76 | 11.88 | 10.89 |
| rib-free portion (\textcircled{3}) | | | | |
| Height difference (\textcircled{4}; i.e., | 3.88 | 3.30 | 2.17 | 2.03 |
| (\textcircled{1} + \textcircled{2}) − \textcircled{3}) | | | | |

As confirmed from the results shown in Tables 4 and 5, all of the cured films prepared from the colored photosensitive resin compositions of Examples 1 to 17 had a total reflectance of 4.6% or less and a specular reflectance, which is the difference between the total reflectance and scattered reflectance, as low as 4.4% or less. Thus, they satisfy a low level of reflectance.

In addition, all of the cured films of Examples 1 to 17 had a desired thickness (3 μm) with a deviation of less than 0.3 μm, they were all capable of being developed within a short period of time, and they were all excellent in optical density and resolution.

In contrast, most of the cured films prepared from the compositions of Comparative Examples 1 to 8 had poor reflectance characteristics, in particular, total reflectance, the development time thereof was either too long or too short, and they were poor in any one or more of resolution and optical density.

In addition, as shown in the photographs of FIGS. 2, 3, 5, and 6, most of the cured films of Examples 1 to 17 were observed with clear and distinct line widths, whereas no pattern was formed or the pattern was not clear in the cured films of Comparative Examples 1 to 8.

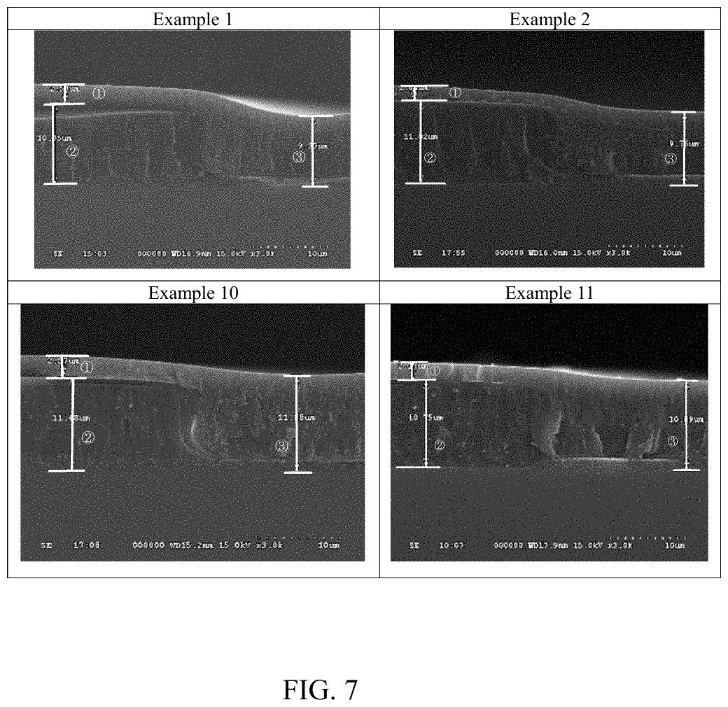

Further, as confirmed from Table 6 and FIG. 7, the cured films prepared from the compositions of Examples 1, 2, 10, and 11 were flat since the height difference between the portion where the ribs were formed and the portion where ribs were not formed is not large.

1. A photosensitive resin composition, which comprises:
(A) a copolymer;
(B) a photopolymerizable compound;
(C) a photopolymerization initiator; and
(D) a colorant,
wherein the colorant (D) comprises at least one colorant selected from the group consisting of a black organic colorant, a black inorganic colorant, and a colorant other than black, and
when a cured film having a thickness of 3 μm formed from the photosensitive resin composition is measured by the SCI method at a wavelength of 360 to 740 nm, it shows a total reflectance of 4.6% or less.

2. The photosensitive resin composition of claim 1, wherein the black organic colorant is at least one selected from the group consisting of aniline black, lactam black, and perylene black.

3. The photosensitive resin composition of claim 1, wherein the colorant (D) comprises 40 to 100% by weight of the black organic colorant based on the total weight of the solids content of the colorant (D).

4. The photosensitive resin composition of claim 1, wherein the colorant (D) comprises 0 to 10% by weight of the black inorganic colorant based on the total weight of the solids content of the colorant (D).

5. The photosensitive resin composition of claim 1, wherein the colorant other than black is at least one selected from the group consisting of a blue colorant and a violet colorant.

6. The photosensitive resin composition of claim 5, wherein the colorant (D) comprises greater than 0 to 50% by weight of the blue colorant and the violet colorant, respectively, based on the total weight of the solids content of the colorant (D).

7. The photosensitive resin composition of claim 1, which further comprises a copolymer (F) different from the copolymer (A),
wherein the copolymer (F) comprises (f-1) a structural unit derived from an ethylenically unsaturated carboxylic acid, an ethylenically unsaturated carboxylic anhydride, or a combination thereof; (f-2) a structural unit derived from a C₃₋₂₀ aliphatic cyclic ethylenically unsaturated compound; (f-3) a structural unit derived from a C₃₋₂₀ aliphatic linear ethylenically unsaturated compound; and (f-4) a structural unit derived from an ethylenically unsaturated compound different from (f-1), (f-2), and (f-3).

8. The photosensitive resin composition of claim 7, wherein the weight average molecular weight of the copolymer (F) is 3,000 to 10,000 Da.

9. A cured film prepared from the photosensitive resin composition of claim 1.

10. The cured film of claim 9, which has an optical density of 0.6 to 2.0/μm.
